(19) United States
(12) Patent Application Publication
(10) Pub. No.: US 2026/0344509 A1
(43) Pub. Date: Oct. 29, 2026

(54) SEMICONDUCTOR PACKAGE HAVING STACKED HIGH SIDE FIELD-EFFECT TRANSISTORS AND STACKED LOW SIDE FIELD-EFFECT TRANSISTORS AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Madhur Bobde, Sunnyvale, CA (US); Long-Ching Wang, Cupertino, CA (US); Guobing Shen, Shanghai (CN); Mary Jane R. Alin, Shanghai (CN); Lin Wang, Shanghai (CN)

(73) Assignee: ALPHA AND OMEGA SEMICONDUCTOR INTERNATIONAL LP, TORONTO (CA)

(21) Appl. No.: 19/188,914

(22) Filed: Apr. 24, 2025

(51) Int. Cl. H10W 90/00; H10W 72/00; H10W 72/60; H10W 90/22

(52) U.S. Cl. CPC H10W 90/00; H10W 90/811; H10W 72/07652; H10W 72/627; H10W 72/637; H10W 90/22; H10W 90/766

(57) ABSTRACT

A semiconductor package comprises a lead frame, a first high side FET, a first low side FET, a first set of metal clips, a second high side FET, a second low side FET, a second set of metal clips, and a molding encapsulation. A method for fabricating a semiconductor package is also disclosed. The method comprises the steps of providing a lead frame; mounting a first high side FET and a first low side FET; mounting a first set of metal clips; mounting a second high side FET and a second low side FET; mounting a second set of metal clips; forming a molding encapsulation; and applying a singulation process.

### FIELD OF THE INVENTION

This invention relates generally to a semiconductor package and a method of making the same. More particularly, the present invention relates to the semiconductor package, having stacked high side field-effect transistors (FETs) and stacked low side FETs and the method of making the same.

### BACKGROUND OF THE INVENTION

In a power device application, the size of a semiconductor package becomes smaller and smaller and the performance requirement becomes higher and higher thereby it is quite challenging to facilitate internal insulation of the semiconductor package.

The semiconductor package of the present disclosure includes stacked high side FETs and stacked low side FETs. A thinned section is introduced to a first metal clip to prevent drain-source short. Another thinned section is introduced to a second metal clip to prevent drain-gate short.

### SUMMARY OF THE INVENTION

The present invention discloses a semiconductor package comprises a lead frame, a first high side FET, a first low side FET, a first set of metal clips, a second high side FET, a second low side FET, a second set of metal clips, and a molding encapsulation.

A method for fabricating a semiconductor package is also disclosed. The method comprises the steps of providing a lead frame; mounting a first high side FET and a first low side FET; mounting a first set of metal clips; mounting a second high side FET and a second low side FET; mounting a second set of metal clips; forming a molding encapsulation; and applying a singulation process.

### BRIEF DESCRIPTION OF THE DRAWINGS

FIG. 1A is a top perspective view, FIG. 1B is a bottom perspective view, FIG. 1C is another bottom perspective view, FIG. 1D is a top view, FIG. 1E is a side view with partial cross-sectional plot, FIG. 1F is another side view with partial cross-sectional plot, and FIG. 1G is an exploded plot of a semiconductor package in examples of the present disclosure.

FIG. 2 is a top perspective view of another semiconductor package in examples of the present disclosure.

FIG. 3 is a flowchart of a process to develop a semiconductor package in examples of the present disclosure.

FIGS. 4A, 4B, 4C, 4D, 4E, 4F, and 4G show top perspective views of the process of FIG. 3 to fabricate the semiconductor package in examples of the present disclosure.

### DETAILED DESCRIPTION OF THE INVENTION

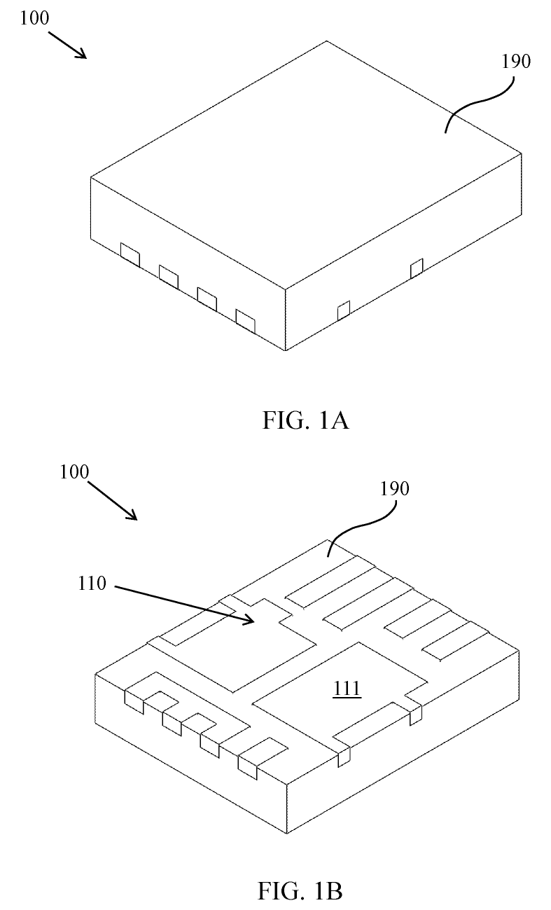

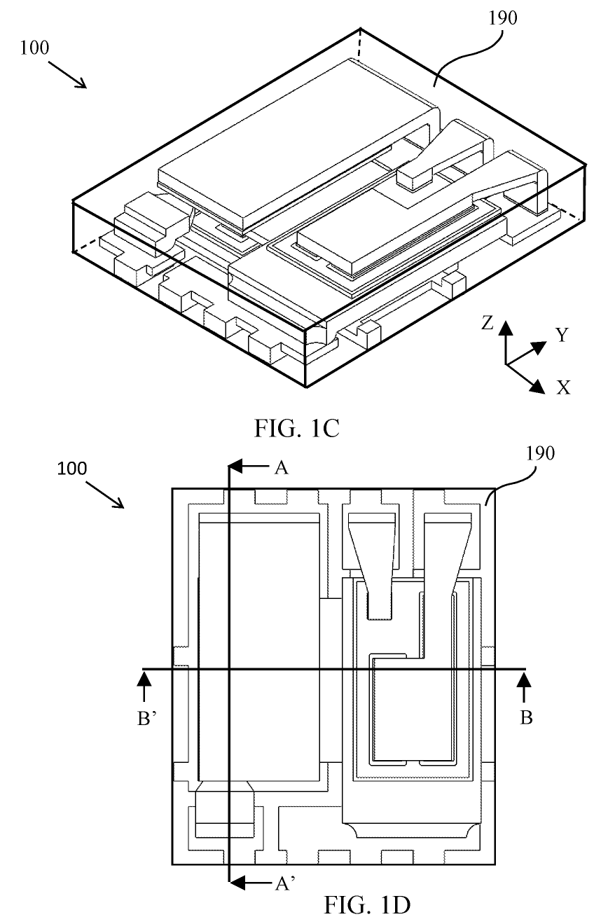

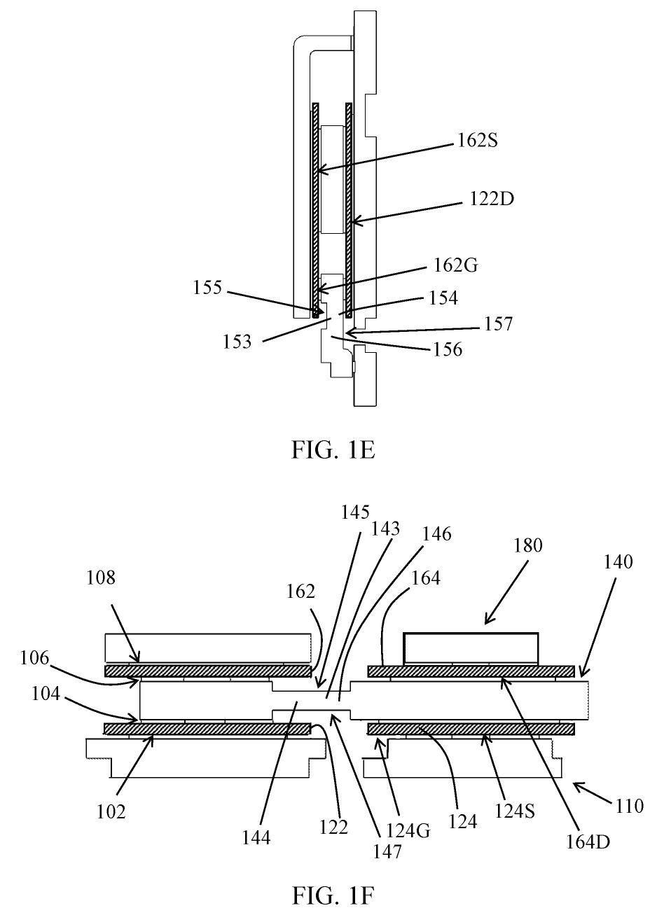

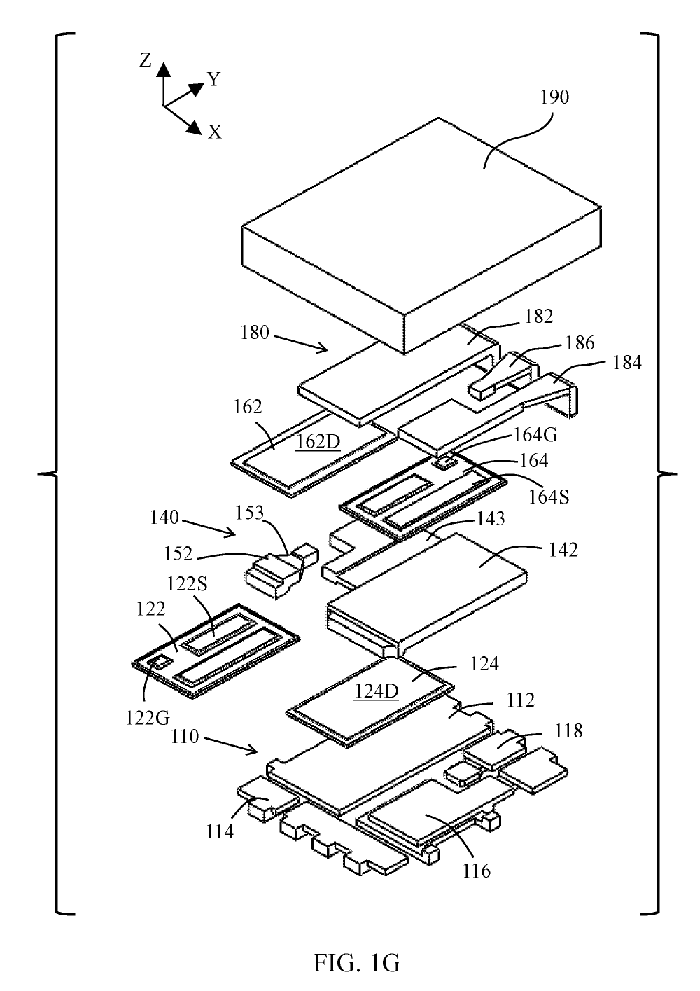

FIG. 1A is a top perspective view, FIG. 1B is a bottom perspective view, FIG. 1C is another bottom perspective view, FIG. 1D is a top view, FIG. 1E is a side view with partial cross-sectional plot, FIG. 1F is another side view with partial cross-sectional plot, and FIG. 1G is an exploded plot of a semiconductor package 100 in examples of the present disclosure. In FIG. 1C, the molding encapsulation is shown in transparent. The partial cross-sectional plot of FIG. 1E is viewed along the direction perpendicular to the AA’ plane of FIG. 1D. The partial cross-sectional plot of FIG. 1F is viewed along the direction perpendicular to the BB’ plane of FIG. 1D.

In examples of the present disclosure, each of the first high side FET 122, the first low side FET 124, the second high side FET 162, and the second low side FET164 is a respective transistor, preferably double-diffused metal-oxide semiconductor (DMOS) FET. The semiconductor package 100 is of a first rectangular prism shape.

Referring now to FIG. 1G, the semiconductor package 100 comprises a lead frame 110, a first high side FET 122, a first low side FET 124, a first set of metal clips 140, a second high side FET 162, a second low side FET 164, a second set of metal clips 180, and a molding encapsulation 190. The first high side FET 122 and the second high side FET 162 are of a second rectangular prism shape. The first low side FET 124 and the second low side FET 164 are of a third rectangular prism shape.

In examples of the present disclosure, referring now to FIG. 1F, the semiconductor package 100 further comprises a first solder layer 102, a second solder layer 104, a third solder layer 106, and a fourth solder layer 108. The first high side FET 122 and the first low side FET 124 are attached to the lead frame 110 by the first solder layer 102. The first set of metal clips 140 is attached to the first high side FET 122 and the first low side FET 124 by the second solder layer 104. The second high side FET 162 and the second low side FET 164 are attached to the first set of metal clips 140 by the third solder layer 106. The second set of metal clips 180 is attached to the second high side FET 162 and the second low side FET 164 by the fourth solder layer 108.

Referring now to FIG. 1G, the lead frame 110 comprises a high side drain pad 112, a high side gate lead 114, a low side source pad 116, and a low side gate lead 118.

Referring now to FIGS. 1E, 1F, and 1G, the first high side FET 122 is attached to the high side drain pad 112. The first high side FET 122 comprises a source electrode 122S and a gate electrode 122G on a front surface of the first high side FET 122, and a drain electrode 122D on a back surface of the first high side FET 122. The first low side FET 124 is flipped and attached to the low side source pad 116. The first low side FET 124 comprises a source electrode 124S and a gate electrode 124G on a front surface of the first low side FET 124, and a drain electrode 124D on a back surface of the first low side FET 124.

The first set of metal clips 140 comprises a first metal clip 142 and a second metal clip 152. The first metal clip 142 connects the source electrode 122S of the first high side FET 122 to the drain electrode 124D of the first low side FET 124. The second metal clip 152 connects the gate electrode 122G of the first high side FET122 to the high side gate lead 114 of the lead frame 110.

The first metal clip 142 comprises a thinned section 143 in a middle portion of the first metal clip 142 to prevent drain-source short of the first and second high side FETs. The thinned section 143 of the first metal clip 142 is between a first recess 145 from a front surface of the first metal clip 142 and a second recess 147 from a back surface of the first metal clip 142 opposite the first recess 145. The thinned section 143 of the first metal clip142 comprises a first portion 144 and a second portion 146. The first portion 144 is positioned between the first high side FET 122 and the second high side FET 162. The second portion 146 is not positioned between the first high side FET 122 and the second high side FET 162.

The second metal clip 152 comprises a thinned section 153 to prevent drain-gate short. The thinned section 153 of the second metal clip 152 is between a first recess 155 and a second recess 157 opposite the first recess 155. the thinned section 153 of the second metal clip 152 comprises a first portion 154 and a second portion 156. The first portion 154 is positioned between the first high side FET 122 and the second high side FET 162. The second portion 156 is not positioned between the first high side FET 122 and the second high side FET 162.

In examples of the present disclosure, the thinned section 143 and the thinned section 153 are formed by coining processes.

The second high side FET 162 is flipped and attached to the first metal clip 142 opposite the first high side FET 122. The second high side FET 162 comprises a source electrode 162S and a gate electrode 162G on a front surface of the second high side FET 162, and a drain electrode 162D on a back surface of the second high side FET 162. The source electrode 162S of the second high side FET 162 is connected to the first metal clip 142. The gate electrode 162G of the second high side FET 162 is connected to the second metal clip 152.

The second low side FET 164 is attached to the first metal clip 142 opposite the first low side FET 124. The second low side FET 164 comprises a source electrode 164S and a gate electrode 164G on a front surface of the second low side FET 164, and a drain electrode 164D on a back surface of the second low side FET 164. The drain electrode 164D of the second low side FET 164 is connected to the first metal clip 142.

The second set of metal clips 180 comprises a third metal clip 182, a fourth metal clip 184, and a fifth metal clip 186. The third metal clip 182 connects the drain electrode 162D of the second high side FET 162 to the high side drain pad 112 of the lead frame 110. The fourth metal clip 184 connects the source electrode 164S of the second low side FET 164 to the low side source pad 116 of the lead frame 110. The fifth metal clip 186 connects the gate electrode164G of the second low side FET 164 to the low side gate lead 118 of the lead frame 110.

The molding encapsulation 190 encloses the first high side FET 122, the first low side FET 124, the first set of metal clips 140, the second high side FET 162, the second low side FET 164, a majority portion of the lead frame 110, and at least a majority portion of the second set of metal clips 180. A majority portion refers to larger than 50%.

In examples of the present disclosure, wherein the semiconductor package 100 excludes bond wires.

Referring now to FIG. 1D, the first high side FET 122 and the first low side FET 124 are positioned side-by-side horizontally (along X-direction). The second high side FET 162 and the second low side FET 164 are positioned side-by-side horizontally (along X-direction). The first high side FET 122 and the second high side FET 162 are aligned vertically (along Z-direction). The first low side FET 124 and the second low side FET 164 are aligned vertically (along Z-direction).

Referring now to FIG. 1B, a bottom surface 111 of the lead frame 110 is exposed from the molding encapsulation 190.

In one example, a respective top surface of each of the third metal clip 282, the fourth metal clip 284, and the fifth metal clip 286 is not exposed from the molding encapsulation 290.

In another example, FIG. 2 is a top perspective view of a semiconductor package 200. A top surface 283 of the third metal clip 282 is exposed from the molding encapsulation 290. A top surface 285 of the fourth metal clip 284 is exposed from the molding encapsulation 290. A top surface of 287 the fifth metal clip 286 is exposed from the molding encapsulation 290.

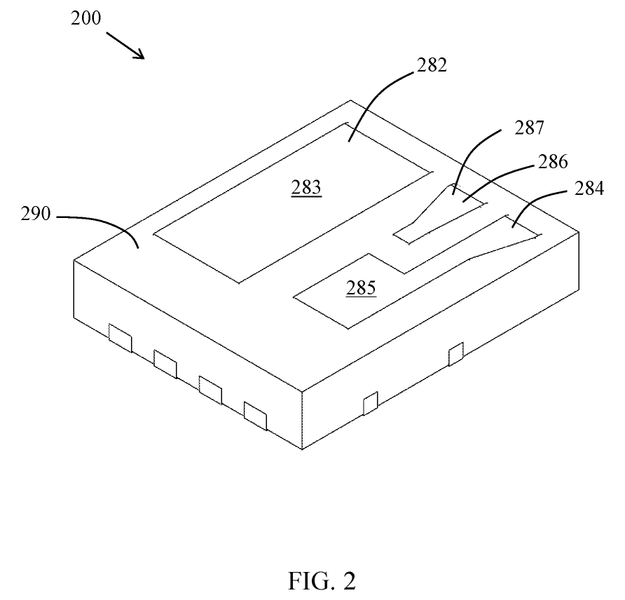

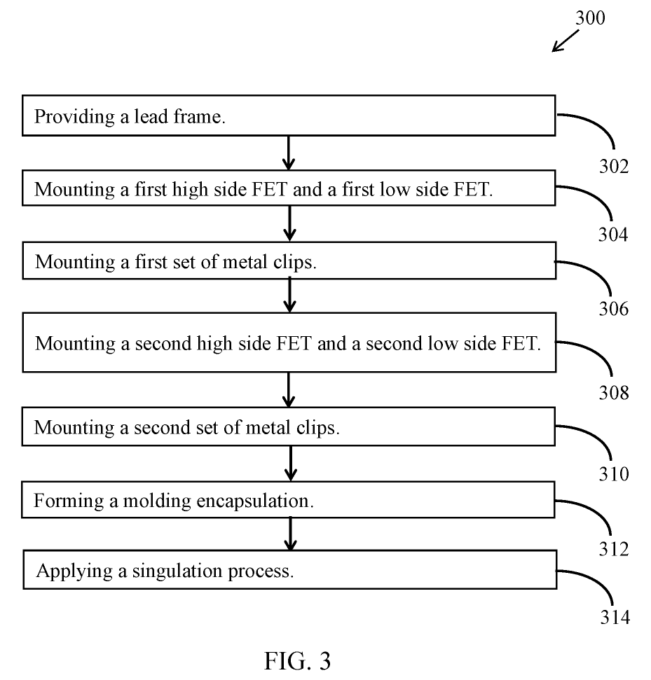

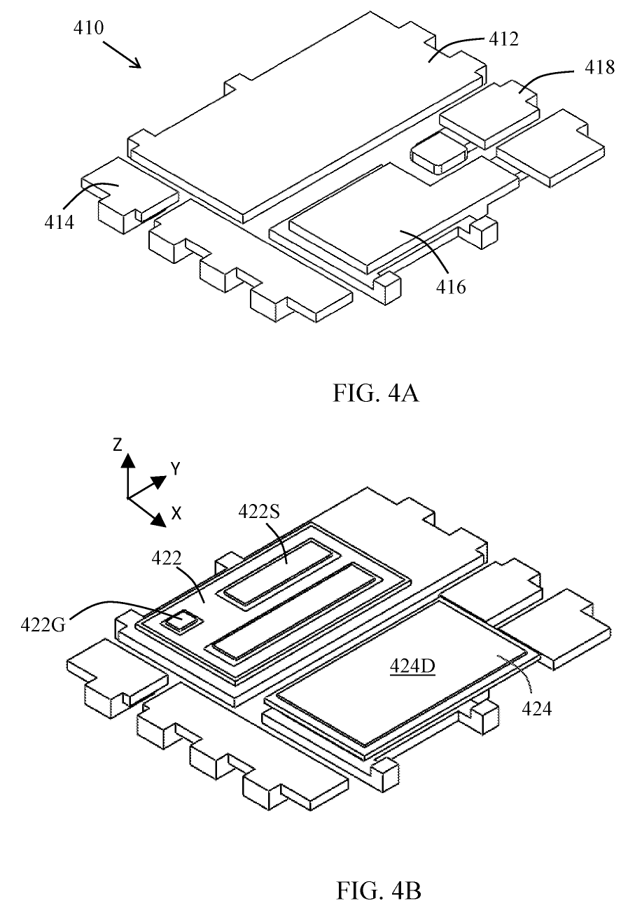

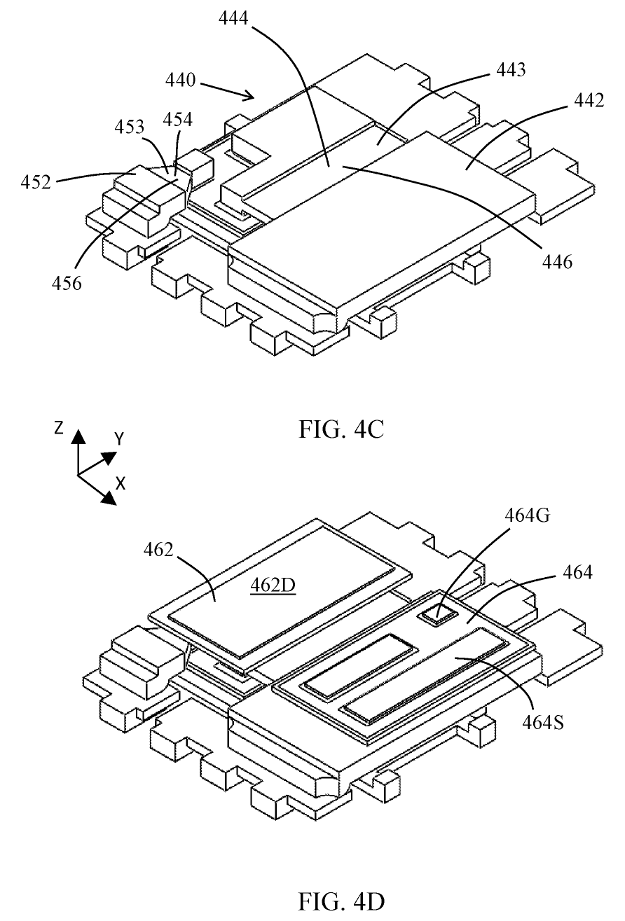

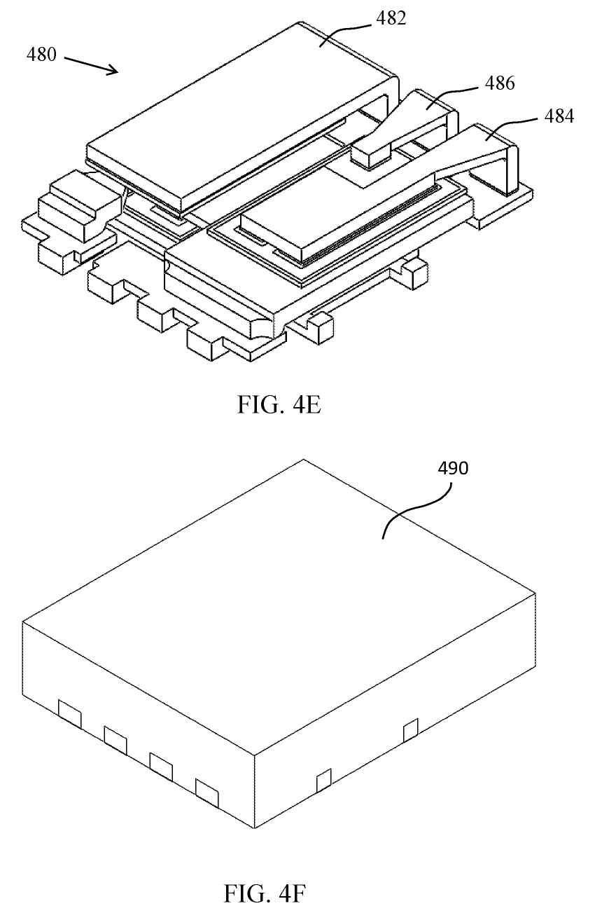

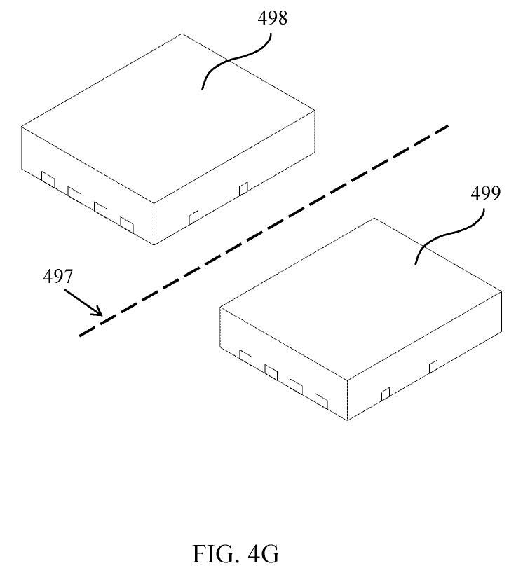

FIG. 3 is a flowchart of a process 300 to develop a semiconductor package in examples of the present disclosure. The process 300 may start from block 302. A plurality of semiconductor packages may be fabricated at the same time. In one example, FIG. 4G shows 2 semiconductor packages are fabricated at the same time. The number of semiconductor packages, fabricated at the same time, may vary. For simplicity, FIGS. 4A-4F show the process steps for fabricating a single semiconductor package.

In block 302, referring now to FIG. 4A, a lead frame 410 is provided. The lead frame 410 comprises a high side drain pad 412, a high side gate lead 414, a low side source pad 416, and a low side gate lead 418. Block 302 may be followed by block 304.

In block 304, the first high side FET 422 and the first low side FET 424 are attached to the lead frame 410 by a first solder layer 102 of FIG. 1F. Referring now to FIG. 4B, the first high side FET 422 is attached to the high side drain pad 412. The first high side FET 422 comprises a source electrode 422S and a gate electrode 422G on a front surface of the first high side FET 422, and a drain electrode 122D of FIG. 1E on a back surface of the first high side FET 422. The first low side FET 424 is flipped and attached to the low side source pad 416. The first low side FET 424 comprises a source electrode 124S of FIG. 1F and a gate electrode 124G of FIG. 1F on a front surface of the first low side FET 424, and a drain electrode 424D on a back surface of the first low side FET 424.

The first high side FET 422 and the first low side FET 424 are positioned side-by-side horizontally (along X-direction). Block 304 may be followed by block 306.

In block 306, referring now to FIG. 4C, a first set of metal clips 440 are mounted by a second solder layer 104 of FIG. 1F. The first set of metal clips 440 comprises a first metal clip 442 and a second metal clip 452. The first metal clip 442 connects the source electrode 422S of the first high side FET 422 to the drain electrode 424D of the first low side FET 424. The second metal clip 452 connects the gate electrode 422G of the first high side FET422 to the high side gate lead 414 of the lead frame 410.

The first metal clip 442 comprises a thinned section 443 to prevent drain-source short. The thinned section 443 of the first metal clip 442 is between a first recess 145 of FIG. 1F and a second recess 147 of FIG. 1F opposite the first recess 145 of FIG. 1F. The thinned section 443 of the first metal clip 442 comprises a first portion 444 and a second portion 446. The first portion 444 is positioned between the first high side FET 422 and the second high side FET 462 of FIG. 4D. The second portion 446 is not positioned between the first high side FET 422 and the second high side FET 462 of FIG. 4D.

The second metal clip 452 comprises a thinned section 453 to prevent drain-gate short. The thinned section 453 of the second metal clip 452 is between a first recess 155 of FIG. 1E and a second recess 157 of FIG. 1E opposite the first recess 155 of FIG. 1E. The thinned section 453 of the second metal clip 452 comprises a first portion 454 and a second portion 456. The first portion 454 is positioned between the first high side FET 422 and the second high side FET 462 of FIG. 4D. The second portion 456 is not positioned between the first high side FET 422 and the second high side FET 462 of FIG. 4D.

In examples of the present disclosure, the thinned section 443 and the thinned section 453 are formed by coining processes. Block 306 may be followed by block 308.

In block 308, referring now to FIG. 4D, a second high side FET 462 and a second low side FET 464 are mounted by a third solder layer 106 of FIG. 1F. The second high side FET 462 is flipped and attached to the first metal clip 442 opposite the first high side FET 422. The second high side FET 462 comprises a source electrode 162S of FIG. 1E and a gate electrode 162G of FIG. 1E on a front surface of the second high side FET 462, and a drain electrode 462D on a back surface of the second high side FET 462. The source electrode 162S of FIG. 1E of the second high side FET 462 is connected to the first metal clip 442. The gate electrode 162G of FIG. 1E of the second high side FET 462 is connected to the second metal clip 452.

The second low side FET 464 is attached to the first metal clip 442 opposite the first low side FET 424. The second low side FET 464 comprises a source electrode 464S and a gate electrode 464G on a front surface of the second low side FET 464, and a drain electrode 164D of FIG. 1F on a back surface of the second low side FET 464. The drain electrode 464D of the second low side FET 464 is connected to the first metal clip 442.

The second high side FET 462 and the second low side FET 464 are positioned side-by-side horizontally (along X-direction). The first high side FET 422 and the second high side FET 462 are aligned vertically (along Z-direction). The first low side FET 424 and the second low side FET 464 are aligned vertically (along Z-direction). Block 308 may be followed by block 310.

In block 310, referring now to FIG. 4E, a second set of metal clips 480 is mounted by a fourth solder layer 108 of FIG. 1F. The second set of metal clips 480 comprises a third metal clip 482, a fourth metal clip 484, and a fifth metal clip 486. The third metal clip 482 connects the drain electrode 462D of the second high side FET 462 to the high side drain pad 412 of the lead frame 410. The fourth metal clip 484 connects the source electrode 464S of the second low side FET 464 to the low side source pad 416 of the lead frame 410. The fifth metal clip 486 connects the gate electrode464G of the second low side FET 464 to the low side gate lead 418 of the lead frame 410. Block 310 may be followed by block 312.

In block 312, referring now to FIG. 4F, a molding encapsulation 490 is formed. The molding encapsulation 490 encloses the first high side FET 422, the first low side FET 424, the first set of metal clips 440, the second high side FET 462, the second low side FET 464, a majority portion of the lead frame 410, and at least a majority portion of the second set of metal clips 480. A majority portion refers to larger than 50%.

In one example, a respective top surface of each of the third metal clip 482, the fourth metal clip 484, and the fifth metal clip 486 is not exposed from the molding encapsulation 490.

In another example, FIG. 2 is a top perspective view of a semiconductor package 200. A top surface 283 of the third metal clip 282 is exposed from the molding encapsulation 290. A top surface 285 of the fourth metal clip 284 is exposed from the molding encapsulation 290. A top surface of 287 the fifth metal clip 286 is exposed from the molding encapsulation 290. Block 312 may be followed by block 314.

Referring now to FIG. 1B, a bottom surface 111 of the lead frame 110 is exposed from the molding encapsulation 190.

In block 314, referring now to FIG. 4G, a singulation process 497 is applied so as to separate the semiconductor package 498 from adjacent semiconductor packages 499. In examples of the present disclosure, each of the semiconductor package 498 and the adjacent semiconductor packages 499 is a respective DMOSFET.

In examples of the present disclosure, the semiconductor package 498 is of a first rectangular prism shape. The first high side FET 422 and the second high side FET 462 are of a second rectangular prism shape. The first low side FET 424 and the second low side FET 464 are of a third rectangular prism shape.

In examples of the present disclosure, wherein the semiconductor package 100 excludes bond wires.

Those of ordinary skill in the art may recognize that modifications of the embodiments disclosed herein are possible. For example, a thickness of the thinned section 143 may vary. Other modifications may occur to those of ordinary skill in this art, and all such modifications are deemed to fall within the purview of the present invention, as defined by the claims.

1. A semiconductor package comprising:
a lead frame comprising:
a high side drain pad,
a high side gate lead,
a low side source pad, and
a low side gate lead,
a first high side field-effect transistor (FET) attached to the high side drain pad, the first high side FET comprising:
a source electrode and a gate electrode on a front surface of the first high side FET, and
a drain electrode on a back surface of the first high side FET,
a first low side FET being flipped and attached to the low side source pad, the first low side FET comprising:
a source electrode and a gate electrode on a front surface of the first low side FET, and
a drain electrode on a back surface of the first low side FET,
a first set of metal clips comprising:
a first metal clip connecting the source electrode of the first high side FET to the drain electrode of the first low side FET, and
a second metal clip connecting the gate electrode of the first high side FET to the high side gate lead of the lead frame,
a second high side FET being flipped and attached to the first metal clip, the second high side FET comprising:
a source electrode and a gate electrode on a front surface of the second high side FET, the source electrode of the second high side FET being connected to the first metal clip, and the gate electrode of the second high side FET being connected to the second metal clip, and
a drain electrode on a back surface of the second high side FET,
a second low side FET attached to the first metal clip, the second low side FET comprising:
a source electrode and a gate electrode on a front surface of the second low side FET, and
a drain electrode on a back surface of the second low side FET, the drain electrode of the second low side FET being connected to the first metal clip,
a second set of metal clips comprising:
a third metal clip connecting the drain electrode of the second high side FET to the high side drain pad of the lead frame,
a fourth metal clip connecting the source electrode of the second low side FET to the low side source pad of the lead frame, and
a fifth metal clip connecting the gate electrode of the second low side FET to the low side gate lead of the lead frame, and
a molding encapsulation enclosing the first high side FET, the first low side FET, the first set of metal clips, the second high side FET, the second low side FET, a majority portion of the lead frame, and at least a majority portion of the second set of metal clips.

2. The semiconductor package of claim 1, wherein the first metal clip comprises a thinned section to prevent drain-source short;
wherein the thinned section of the first metal clip is between a first recess and a second recess opposite the first recess; and
wherein the thinned section of the first metal clip comprises:
a first portion positioned between the first high side FET and the second high side FET, and
a second portion not positioned between the first high side FET and the second high side FET.

3. The semiconductor package of claim 1, wherein the second metal clip comprises a thinned section to prevent drain-gate short;
wherein the thinned section of the second metal clip is between a first recess and a second recess opposite the first recess; and
wherein the thinned section of the second metal clip comprises:
a first portion positioned between the first high side FET and the second high side FET, and
a second portion not positioned between the first high side FET and the second high side FET.

4. The semiconductor package of claim 1, wherein a top surface of the third metal clip is exposed from the molding encapsulation;
wherein a top surface of the fourth metal clip is exposed from the molding encapsulation; and
wherein a top surface of the fifth metal clip is exposed from the molding encapsulation.

5. The semiconductor package of claim 4, wherein a bottom surface of the lead frame is exposed from the molding encapsulation.

6. The semiconductor package of claim 1, wherein the semiconductor package excludes bond wires.

7. The semiconductor package of claim 1, wherein the first high side FET and the first low side FET are positioned side-by-side horizontally; and
wherein the second high side FET and the second low side FET are positioned side-by-side horizontally.

8. The semiconductor package of claim 7, wherein the first high side FET and the second high side FET are aligned vertically; and
wherein the first low side FET and the second low side FET are aligned vertically.

9. The semiconductor package of claim 1, wherein each of the first high side FET, the first low side FET, the second high side FET, and the second low side FET is a respective double-diffused metal-oxide semiconductor (DMOS) FET.

10. A method for fabricating a semiconductor package, the method comprising the steps of:
providing a lead frame comprising:
a high side drain pad,
a high side gate lead,
a low side source pad, and
a low side gate lead;
mounting a first high side field-effect transistor (FET) on the high side drain pad and mounting a first low side FET on the low side source pad by a first solder layer, the first low side FET being flipped,
the first high side FET comprising:
a source electrode and a gate electrode on a front surface of the first high side FET, and
a drain electrode on a back surface of the first high side FET, and
the first low side FET comprising:
a source electrode and a gate electrode on a front surface of the first low side FET, and
a drain electrode on a back surface of the first low side FET;
mounting a first set of metal clips by a second solder layer, the first set of metal clips comprising:
a first metal clip connecting the source electrode of the first high side FET to the drain electrode of the first low side FET, and
a second metal clip connecting the gate electrode of the first high side FET to the high side gate lead of the lead frame,
mounting a second high side FET on the first metal clip and mounting a second low side FET on the first metal clip by a third solder layer, the second high side FET being flipped,
the second high side FET comprising:
a source electrode and a gate electrode on a front surface of the second high side FET, the source electrode of the second high side FET being connected to the first metal clip, and the gate electrode of the second high side FET being connected to the second metal clip, and
a drain electrode on a back surface of the second high side FET,
the second low side FET comprising:
a source electrode and a gate electrode on a front surface of the second low side FET, and
a drain electrode on a back surface of the second low side FET, the drain electrode of the second low side FET being connected to the first metal clip,
mounting a second set of metal clips by a fourth solder layer, the second set of metal clips comprising:
a third metal clip connecting the drain electrode of the second high side FET to the high side drain pad of the lead frame,
a fourth metal clip connecting the source electrode of the second low side FET to the low side source pad of the lead frame, and
a fifth metal clip connecting the gate electrode of the second low side FET to the low side gate lead of the lead frame;
forming a molding encapsulation enclosing the first high side FET, the first low side FET, the first set of metal clips, the second high side FET, the second low side FET, a majority portion of the lead frame, and at least a majority portion of the second set of metal clips; and
applying a singulation process separating the semiconductor package from adjacent semiconductor packages.

11. The method of claim 10, wherein the first metal clip comprises a thinned section to prevent drain-source short;
wherein the thinned section of the first metal clip is between a first recess and a second recess opposite the first recess; and
wherein the thinned section of the first metal clip comprises:
a first portion positioned between the first high side FET and the second high side FET, and
a second portion not positioned between the first high side FET and the second high side FET.

12. The method of claim 10, wherein the second metal clip comprises a thinned section to prevent drain-gate short;
wherein the thinned section of the second metal clip is between a first recess and a second recess opposite the first recess; and
wherein the thinned section of the second metal clip comprises:
a first portion positioned between the first high side FET and the second high side FET, and
a second portion not positioned between the first high side FET and the second high side FET.

13. The method of claim 10, wherein a top surface of the third metal clip is exposed from the molding encapsulation;
wherein a top surface of the fourth metal clip is exposed from the molding encapsulation; and
wherein a top surface of the fifth metal clip is exposed from the molding encapsulation.

14. The method of claim 13, wherein a bottom surface of the lead frame is exposed from the molding encapsulation.

15. The method of claim 10, wherein the semiconductor package excludes bond wires.

16. The method of claim 10, wherein the first high side FET and the first low side FET are positioned side-by-side horizontally; and
wherein the second high side FET and the second low side FET are positioned side-by-side horizontally.

17. The method of claim 10, wherein the first high side FET and the second high side FET are aligned vertically; and
wherein the first low side FET and the second low side FET are aligned vertically.

18. The method of claim 10, wherein each of the first high side FET, the first low side FET, the second high side FET, and the second low side FET is a respective double-diffused metal-oxide semiconductor (DMOS) FET.
